(19) United States
(12) Patent Application Publication
(10) Pub. No.: US 2024/0055273 A1
(43) Pub. Date: Feb. 15, 2024

(54) Wet Etching Solution and Wet Etching Method

(71) Applicant: Central Glass Company, Limited, Ube-shi, Yamaguchi (JP)

(72) Inventors: Takahisa TANIGUCHI, Tokyo (JP); Chih-Chien LIN, Tokyo (JP); Tatsuo MIYAZAKI, Tokyo (JP)

(21) Appl. No.: 18/271,185

(22) PCT Filed: Jan. 4, 2022
(86) PCT No.: PCT/JP2022/000013

§ 371 Date: Jul. 6, 2023

(30) Foreign Application Priority Data
Jan. 7, 2021 (JP) 2021-001370

(51) Int. Cl. H01L 21/3213; C23F 1/44; H01L 21/311

(52) U.S. Cl. CPC H01L 21/32134; C23F 1/44; H01L 21/31111

(57) ABSTRACT

A wet etching solution according to the present disclosure is an etching solution for selectively removing a second metal layer made of at least one of a cobalt-based material or a copper-based material from a semiconductor substrate while suppressing etching of a first metal layer made of a tungsten-based material, the first metal layer and the second metal layer being co-present on the semiconductor substrate, an oxide layer being formed on a surface layer of at least the at least one of a cobalt-based material or a copper-based material. The wet etching solution includes a solution in which a β-diketone containing a trifluoromethyl group and a carbonyl group bonded together is dissolved in an organic solvent.

### TECHNICAL FIELD

The present disclosure relates to a wet etching solution and a wet etching method each for use in a semiconductor device manufacturing process, etc.

BACKGROUND ART

In a semiconductor device manufacturing process, etching is performed to form a desired pattern, e.g., a desired wiring pattern, on a substrate by removing unnecessary portions of a metal-containing film, such as a metal film used as a metal gate material, an electrode material, a magnetic material, etc., or a metal compound film used as a piezoelectric material, an LED luminescent material, a transparent electrode material, a dielectric material, etc.

As the etching method, the following methods are known: (1) dry etching using reactive species in plasma; and (2) wet etching using chemicals such as inorganic acids and organic acids. Usually, dry etching is used for high precision microprocessing.

Although wet etching is advantageous in terms of low cost, high productivity, capability of batch processing, etc., it has difficulty in selectively removing a specific metal or metal compound layer formed on a substrate with respect to another co-present metal or metal compound layer in the microprocessing of a semiconductor device. Thus, various wet etching solutions have been developed which are formed of compositions of inorganic or organic compounds with high etching selectivity.

Patent Literature 1 discloses a solution containing a mixture of dilute hydrogen fluoride and a silane-containing precursor which can selectively etch titanium while suppressing etching of tungsten, etc. Patent Literature 2 discloses a solution containing hydrogen peroxide, an organic acid salt, and water which can selectively etch a titanium-based metal, a tungsten-based metal, a titanium-tungsten-based metal, or a nitride thereof with respect to another metal or substrate material. Patent Literature 3 discloses an etching solution containing ammonium oxalate, hydrogen peroxide, and a surfactant and having a pH of 6.0 to 8.5 which can selectively and uniformly etch copper or a copper alloy even when another metal is co-present. Patent Literature 4 discloses an etching solution which can treat a substrate having a first layer containing TiN and a second layer containing a metal selected from transition metals of groups 3-11 in the Periodic Table to selectively remove the first layer, and which contains an inorganic compound, an oxidant, and an anticorrosive for the second layer.

Moreover, Patent Literature 5 discloses an organic solvent solution containing a β-diketone in which a trifluoromethyl group and a carbonyl group are bonded together, which can etch a metal film such as Co or Fe capable of forming a complex with the β-diketone. Use of this solution enables selective etching between the metal film and a semiconductor substrate of a silicon material or other material which does not form a complex with the β-diketone.

In recent years, the fully-self-aligned via (FSAV) process has been suggested for connection between upper and lower conductor layers through a via.

Patent Literature 6 discloses, as a substrate processing method capable of controlling the etching amount of a metal layer with subnanometer precision, a method which repeats the formation of an oxidized metal layer including one or more atomic layers on a surface layer of a metal layer such as Co or Cu embedded in a trench on the surface of a substrate and the selective etching of the oxidized metal layer with an inorganic acidic chemical to remove several tens of nanometers of the metal layer.

### CITATION LIST

### Patent Literature

Patent Literature 1: JP 4896995 B

Patent Literature 2: JP 5523325 B

Patent Literature 3: WO 2006/103751

Patent Literature 4: JP 2014-093407 A

Patent Literature 5: JP 2017-28257 A

Patent Literature 6: JP 2019-061978 A

### SUMMARY OF INVENTION

### Technical Problem

Usually, dry etching is used for high precision microprocessing. However, in dry etching of a thin metal film on which a natural oxide film can be easily formed, etching is inhibited by the thin oxide layer. Although Patent Literature 6 discloses, as a method for etching a metal layer such as Co or Cu with high precision, a method which repeats the formation of an oxidized metal layer having a nanometer-order thickness and the removal of the oxidized metal layer by etching, this method requires the use of an acidic aqueous solution such as hydrofluoric acid or hydrochloric acid as the etchant.

As the required properties of etchants for wiring metal materials such as Co and Cu, no deterioration of the surface roughness of wiring metal materials after etching, as well as etching selectivity with respect to other wiring metal materials (e.g., tungsten), substrate materials, stopper materials, etc. are important.

The present disclosure relates to the etching of a Co or Cu metal layer of wirings, etc. for use in a semiconductor device manufacturing process, etc. The present disclosure aims to provide a wet etching solution capable of removing an oxide layer of the metal layer without using an acidic aqueous solution, and an etching method capable of removing the metal layer by only a desired thickness of several tens of nanometers or less using the solution.

### Solution to Problem

As a result of extensive studies, the present inventors have found that when an organic solvent solution of a β-diketone in which a trifluoromethyl group and a carbonyl group are bonded together is used as an etching solution, while a cobalt and/or copper oxide film can be etched at an etching rate similar to that of a metal film, a tungsten oxide film cannot be easily etched, and therefore that cobalt and/or copper can be selectively etched with respect to tungsten by utilizing metal oxide films. This finding has led to the present disclosure.

Specifically, the present disclosure is as follows.

<1> A wet etching solution for selectively removing a second metal layer made of at least one of a cobalt-based material or a copper-based material from a semiconductor substrate while suppressing etching of a first metal layer made of a tungsten-based material, the first metal layer and the second metal layer being co-present on the semiconductor substrate, an oxide layer being formed on a surface layer of at least the at least one of a cobalt-based material or a copper-based material,
the etching solution including a solution in which a β-diketone containing a trifluoromethyl group and a carbonyl group bonded together is dissolved in an organic solvent.

The present disclosure also includes the following embodiments <2> to <8>.

<2> The wet etching solution according to <1>, wherein a material of the semiconductor substrate is a silicon-based material or a silicate glass material.

<3> The wet etching solution according to <1> or <2>, wherein the β-diketone is present at a concentration of 1 to 80 mass %.

<4> The wet etching solution according to any one of <1> to <3>, wherein the etching solution has a moisture content of 1 mass % or less.

<5> A wet etching method of selectively removing a second metal layer made of at least one of a cobalt-based material or a copper-based material with respect to a first metal layer made of a tungsten-based material, the method including:
a first step of preparing a semiconductor substrate on which the first metal layer and the second metal layer are co-present;
a second step of preparing an etching solution which includes a solution in which a β-diketone containing a trifluoromethyl group and a carbonyl group bonded together is dissolved in an organic solvent;
a third step of bringing an oxidant into contact with the semiconductor substrate to form a second metal oxide layer on a surface layer of at least the second metal layer; and
a fourth step of bringing the etching solution into contact with the second metal oxide layer.

<6> The wet etching method according to <5>, wherein in the third step, the oxidant is oxygen, air, ozone, or a peroxide.

<7> The wet etching method according to <5> or <6>, wherein the fourth step includes bringing the etching solution into contact with the second metal oxide layer after degassing the etching solution.

<8> The wet etching method according to <5>, wherein the third step and the fourth step are simultaneously performed using a solution in which at least one gas selected from oxygen, air, and ozone as the oxidant is dissolved in the etching solution.

Here, the expression “second metal layer made of at least one of a cobalt-based material or a copper-based material” encompasses any of the following embodiments: “a second metal layer made of elemental cobalt, a cobalt-containing alloy, or a cobalt-containing compound”; “a second metal layer made of elemental copper, a copper-containing alloy, or a copper-containing compound”; “a second metal layer made of an alloy containing cobalt and copper or a compound containing cobalt and copper; and “an embodiment in which a second metal layer made of elemental cobalt, a cobalt-containing alloy, or a cobalt-containing compound is co-present with a second metal layer made of elemental copper, a copper-containing alloy, or a copper-containing compound”.

### Advantageous Effects of Invention

The etching solution of the present disclosure and the etching method using the solution enable selective etching of cobalt and/or copper with respect to tungsten without using an acidic aqueous solution in the etching of a metal layer for use in a semiconductor device manufacturing process, etc.

### DESCRIPTION OF EMBODIMENTS

Hereinafter, the present disclosure is described in detail. The present disclosure is not limited to the following embodiments and can be appropriately implemented based on the common knowledge of those skilled in the art without departing from the gist of the present disclosure.

### <Wet Etching Solution>

The wet etching solution of the present disclosure is an etching solution for selectively removing a second metal layer made of at least one of a cobalt-based material or a copper-based material (cobalt- and/or copper-based material) from a semiconductor substrate while suppressing etching of a first metal layer made of a tungsten-based material, wherein the first metal layer and the second metal layer are co-present on the semiconductor substrate, and an oxide layer is formed on a surface layer of at least the cobalt- and/or copper-based material.

The first metal layer is formed of an elemental tungsten film, a tungsten-containing alloy film, or a film of a tungsten-based material (hereinafter sometimes referred to simply as “tungsten” or “first metal”) such as a compound composed of two or more metals including tungsten, such as TiW, TiWN, or WSi₂. Moreover, the second metal layer is formed of an elemental cobalt and/or copper film, a cobalt- and/or copper-containing alloy film, or a film of a cobalt- and/or copper-based material (hereinafter sometimes referred to simply as “cobalt and/or copper” or “second metal”) such as a cobalt- and/or copper-containing compound. It should be noted that, when the second metal layer is a metal layer containing multiple elements, the elements may be present in any proportion.

Herein, the term “co-present” is used to refer to a structure in which a first metal layer formed of a film of a tungsten-based material and a second metal layer formed of a film of a cobalt- and/or copper-based material are each exposed on a semiconductor substrate, or a structure in which at least the second metal layer is exposed on the semiconductor substrate.

The etching solution of the present disclosure is a solution in which a β-diketone containing a trifluoromethyl group and a carbonyl group bonded together (hereinafter sometimes referred to simply as “β-diketone”) is dissolved in an organic solvent. The β-diketone containing a trifluoromethyl group (CF₃) and a carbonyl group (C=O) bonded together is capable of etching at a high rate and does not easily cause aggregation of a complex with the metal to be etched and precipitation of a solid, as compared to a β-diketone in which a trifluoromethyl group and a carbonyl group are not bonded together.

Specific examples of the β-diketone containing a trifluoromethyl group and a carbonyl group bonded together include compounds such as hexafluoroacetylacetone (1,1,1,5,5,5-hexafluoro-2,4-pentanedione; herein, sometimes abbreviated as “HFAc”), trifluoroacetylacetone (1,1,1-trifluoro-2,4-pentanedione), 1,1,1,6,6,6-hexafluoro-2,4-hexanedione, 4,4,4-trifluoro-1-(2-thienyl)-1,3-butanedione, 4,4,4-trifluoro-1-phenyl-1,3-butanedione, 1,1,1,5,5,5-hexafluoro-3-methyl-2,4-pentanedione, 1,1,1,3,5,5,5-heptafluoro-2,4-pentanedione, and 1,1,1-trifluoro-5,5-dimethyl-2,4-hexanedione. These may be used alone or in combinations of two or more.

The organic solvent used in the etching solution may be any conventionally known organic solvent that can dissolve the β-diketone and that causes only slight damage to the surface of a workpiece.

Suitable examples of the organic solvent include alcohols, hydrocarbons, esters, ethers, ketones, halogen element-containing solvents, sulfoxides, lactones, carbonates, polyhydric alcohol derivatives, nitrogen element-containing solvents, and silicones, and mixtures of the foregoing organic solvents.

Among these, hydrocarbons, esters, ethers, halogen element-containing solvents, and polyhydric alcohol derivatives without OH groups, and mixtures of the foregoing may be used. These are preferred because their use improves the stability of the etching solution.

Examples of the hydrocarbons include n-hexane, n-heptane, n-octane, n-nonane, n-decane, n-undecane, n-dodecane, n-tetradecane, n-hexadecane, n-octadecane, n-icosane, and branched hydrocarbons corresponding to the numbers of carbons of the foregoing hydrocarbons (e.g., isododecane, isocetane), cyclohexane, methylcyclohexane, decaline, benzene, toluene, xylene, (ortho-, meta-, or para-)diethylbenzene, 1,3,5-trimethylbenzene, and naphthalene.

Examples of the esters include ethyl acetate, n-propyl acetate, i-propyl acetate, n-butyl acetate, i-butyl acetate, n-pentyl acetate, i-pentyl acetate, n-hexyl acetate, n-heptyl acetate, n-octyl acetate, n-pentyl formate, n-butyl propionate, ethyl butyrate, n-propyl butyrate, i-propyl butyrate, n-butyl butyrate, methyl n-octanoate, methyl decanoate, methyl pyruvate, ethyl pyruvate, n-propyl pyruvate, methyl acetoacetate, ethyl acetoacetate, ethyl 2-oxobutanoate, dimethyl adipate, methyl 3-methoxypropionate, ethyl 3-methoxypropionate, methyl 3-ethoxypropionate, ethyl 3-ethoxypropionate, and ethyl ethoxyacetate.

Examples of the ethers include di-n-propyl ether, ethyl-n-butyl ether, di-n-butyl ether, ethyl-n-amyl ether, di-n-amyl ether, ethyl-n-hexyl ether, di-n-hexyl ether, di-n-octyl ether, and ethers containing branched hydrocarbon groups corresponding to the numbers of carbons of the foregoing ethers, such as diisopropyl ether and diisoamyl ether, dimethyl ether, diethyl ether, methyl ethyl ether, methyl cyclopentyl ether, diphenyl ether, tetrahydrofuran, dioxane, methyl perfluoropropyl ether, methyl perfluorobutyl ether, ethyl perfluorobutyl ether, methyl perfluorohexyl ether, and ethyl perfluorohexyl ether.

Examples of the ketones include acetone, acetylacetone, methyl ethyl ketone, methyl propyl ketone, methyl butyl ketone, 2-heptanone, 3-heptanone, cyclohexanone, and isophorone.

Examples of the halogen element-containing solvents include perfluorocarbons such as perfluorooctane, perfluorononane, perfluorocyclopentane, perfluorocyclohexane, and hexafluorobenzene; hydrofluorocarbons such as 1,1,1,3,3-pentafluorobutane, octafluorocyclopentane, 2,3-dihydrodecafluoropentane, and ZEORORA H (available from Zeon Corporation); hydrofluoroethers such as methyl perfluoroisobutyl ether, methyl perfluorobutyl ether, ethyl perfluorobutyl ether, ethyl perfluoroisobutyl ether, ASAHIKLIN AE-3000 (available from AGC), and Novec 7100, Novec 7200, Novec 7300, and Novec 7600 (all available from 3M); chlorocarbons such as tetrachloromethane; hydrochlorocarbons such as chloroform; chlorofluorocarbons such as dichlorodifluoromethane; hydrochlorofluorocarbons such as 1,1-dichloro-2,2,3,3,3-pentafluoropropane, 1,3-dichloro-1,1,2,2,3-pentafluoropropane, 1-chloro-3,3,3-trifluoropropene, and 1,2-dichloro-3,3,3-trifluoropropene; perfluoroethers; and perfluoropolyethers.

Examples of the sulfoxides include dimethylsulfoxide (DMSO).

Examples of the lactones include β-propiolactone, γ-butyrolactone, γ-valerolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, and ε-hexanolactone.

Examples of the carbonates include dimethyl carbonate, ethyl methyl carbonate, diethyl carbonate, and propylene carbonate.

Examples of the polyhydric alcohol derivatives include ethylene glycol monomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monopropyl ether, diethylene glycol monobutyl ether, triethylene glycol monomethyl ether, triethylene glycol monoethyl ether, triethylene glycol monopropyl ether, triethylene glycol monobutyl ether, tetraethylene glycol monomethyl ether, tetraethylene glycol monoethyl ether, tetraethylene glycol monopropyl ether, tetraethylene glycol monobutyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tripropylene glycol monoethyl ether, tripropylene glycol monopropyl ether, tripropylene glycol monobutyl ether, tetrapropylene glycol monomethyl ether, butylene glycol monomethyl ether, ethylene glycol dimethyl ether, ethylene glycol diethyl ether, ethylene glycol dibutyl ether, ethylene glycol monomethyl ether acetate, ethylene glycol monoethyl ether acetate, ethylene glycol monobutyl ether acetate, ethylene glycol diacetate, diethylene glycol dimethyl ether, diethylene glycol ethyl methyl ether, diethylene glycol diethyl ether, diethylene glycol butyl methyl ether, diethylene glycol dibutyl ether, diethylene glycol monomethyl ether acetate, diethylene glycol monoethyl ether acetate, diethylene glycol monobutyl ether acetate, diethylene glycol diacetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol dimethyl ether, propylene glycol diethyl ether, propylene glycol dibutyl ether, propylene glycol monomethyl ether acetate (PGMEA), propylene glycol monoethyl ether acetate, propylene glycol monobutyl ether acetate, propylene glycol diacetate, dipropylene glycol dimethyl ether, dipropylene glycol methyl propyl ether, dipropylene glycol diethyl ether, dipropylene glycol dibutyl ether, dipropylene glycol monomethyl ether acetate, dipropylene glycol monoethyl ether acetate, dipropylene glycol monobutyl ether acetate, dipropylene glycol diacetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol dimethyl ether, butylene glycol monomethyl ether acetate, butylene glycol diacetate, and glycerol triacetate.

Examples of the nitrogen element-containing solvents include formamide, N,N-dimethylformamide, N,N-dimethylacetamide, N-diethylacetamide, N-methyl-2-pyrrolidone, N-ethyl-2-pyrrolidone, N-propyl-2-pyrrolidone, 1,3-dimethyl-2-imidazolidinone, 1,3-diethyl-2-imidazolidinone, 1,3-diisopropyl-2-imidazolidinone, alkylamine, dialkylamine, trialkylamine, and pyridine.

Examples of the silicones include hexamethyldisiloxane, octamethyltrisiloxane, decamethyltetrasiloxane, and dodecamethylpentasiloxane.

The β-diketone concentration in the etching solution is usually in the range of 1 to 80 mass %, preferably 1 to 50 mass %, more preferably 1 to 10 mass %. While a β-diketone concentration of more than 80 mass % does not affect the etching performance, the β-diketone is generally more expensive than organic solvents and exhibits sufficient etching performance even at a concentration in the range indicated above. Thus, from an economic point of view, there are not many advantages to actively using a large amount of β-diketone. It should be noted that, when the β-diketone concentration is less than 1 mass %, etching may not proceed if the amount of β-diketone is too small.

Moreover, since the β-diketone will precipitate as a solid once it forms a hydrate, the use of water as a solvent results in the formation of a hydrate and therefore the precipitation of a solid, making it difficult to use the solution as an etching solution.

Thus, the etching solution preferably has a moisture content of 1 mass % or less. Since the β-diketone will precipitate as a solid once it forms a hydrate, a high moisture content can lead to the formation of particles of solid components in the etching solution. Such an etching solution with particles may leave the particles on a workpiece, causing device failure.

Here, although the details of the etching solution are as described above, the etching solution may be composed of only an organic solvent and the β-diketone or may further contain various acids as additives in order to enhance the etching rate and etching selectivity as long as the workpiece is not adversely affected.

The type of acid is preferably at least one selected from the group consisting of citric acid, formic acid, acetic acid, and trifluoroacetic acid. The amount of the additives is preferably 0.01 to 20 mass %, more preferably 0.5 to 15 mass %, still more preferably 1 to 10 mass % of the etching solution. Moreover, the etching solution may be composed of only an organic solvent, the β-diketone, and any of the additives.

### <Wet Etching Method>

The wet etching method of the present disclosure is a wet etching method of selectively removing a second metal layer made of at least one of a cobalt-based material or a copper-based material (cobalt- and/or copper-based material) with respect to a first metal layer made of a tungsten-based material, wherein the method includes:
a first step of preparing a semiconductor substrate on which the first metal layer and the second metal layer are co-present;
a second step of preparing an etching solution which includes a solution in which a β-diketone containing a trifluoromethyl group and a carbonyl group bonded together is dissolved in an organic solvent;
a third step of bringing an oxidant into contact with the semiconductor substrate to form a second metal oxide layer on a surface layer of at least the second metal layer; and
a fourth step of bringing the etching solution into contact with the second metal oxide layer.

In the present disclosure, the wet etching method may be performed with any device and any process in the third step of bringing an oxidant into contact with the semiconductor substrate and in the fourth step of bringing the etching solution into contact with the second metal oxide layer. Examples include a single wafer process using a spinning device which can treat semiconductor substrates one by one by supplying an etching solution to the vicinity of the center of rotation while rotating the semiconductor substrates held substantially horizontally; and a batch process using a device which can treat a plurality of semiconductor substrates by immersion in a bath.

Further, the third step and the fourth step may be repeatedly performed. Repeatedly performing these steps can increase the etching amount, with only slight deterioration of the surface roughness.

The use of the wet etching method of the present disclosure permits the use of wet etching devices that are less expensive than dry etching devices. Thus, semiconductor devices can be produced at low cost. Examples of the semiconductor devices mentioned here include solar cells, hard disk drives, logic integrated circuits (ICs), microprocessors, dynamic random access memory devices, phase change memory devices, ferroelectric memory devices, magnetoresistive memory devices, resistance change memory devices, and micro-electro-mechanical systems (MEMS).

### <First Step>

The first step is a step of preparing a semiconductor substrate. Specifically, the semiconductor substrate used is one on which a first metal layer made of a tungsten-based material and a second metal layer made of a cobalt- and/or copper-based material are co-present.

The semiconductor substrate may be made of any material that can form a substrate for any of various thin films and that does not react with the etching solution during wet etching. Examples include substrates made of silicon-based materials such as silicon oxide, polysilicon, silicon nitride, silicon oxynitride, and silicon carbide; nitride-based substrates such as GaN and AlN; and silicate glass materials such as soda lime glass, borosilicate glass, and quartz glass.

Moreover, the first and second metal layers that are co-present on the semiconductor substrate may be produced by forming films on the semiconductor substrate or on a thin film of the semiconductor substrate with any of various thin films formed thereon. Any film formation method may be used. Examples of applicable methods include sputtering, chemical vapor deposition (CVD), and atomic layer deposition (ALD). It should be noted that one or more of these film formation methods may be used alone or in combination to form films.

The first metal layer may be a film made of elemental tungsten, a film of a tungsten-containing alloy, or a film of a compound composed of two or more metals including tungsten. The second metal layer may be a film made of elemental cobalt or copper, a film of a cobalt- and/or copper-containing alloy, or a film of a cobalt- and/or copper-containing compound. It should be noted that, when the second metal layer is a metal layer containing multiple elements, the elements may be present in any proportion.

Moreover, when any of the film formation methods is used to form the first or second metal layer on the semiconductor substrate, first, a barrier metal layer may be formed, and then the first or second metal layer may be formed on the surface of the barrier metal layer formed.

A known method for forming a metal wiring includes forming a wiring groove in an insulating film formed on a semiconductor substrate, forming a metal film such that the metal film fills the groove, and etching the metal film to expose the insulating film, whereby a metal wiring is embedded in the wiring groove and the excess metal film on the insulating film, except for the wiring groove, is removed, thereby forming a metal wiring. Here, for use as a wiring material, a barrier metal layer is preferably provided around the metal in order to prevent diffusion of the metal into the insulating film and corrosion of the metal.

The barrier metal layer mentioned here is a layer (also referred to as “anti-diffusion layer”) for preventing diffusion of the metal into the insulating film, corrosion of the metal, current leakage, etc. The barrier metal layer may be an elemental metal or a metal compound, such as tantalum (Ta), tantalum nitride (TaN), titanium (Ti), or titanium nitride (TiN), or a laminated film of the foregoing. The laminated film may be, for example, one in which TaN and Ta are laminated in the stated order or one in which Ti and TiN are laminated in the stated order.

In a specific example, first, a wiring groove is formed in an insulating film by lithography and anisotropic etching. Subsequently, tantalum nitride or tantalum as a barrier metal layer is formed on the inner surface of the wiring groove. Next, a metal film is formed on the insulating film so as to fill the wiring groove, and the excess metal film and barrier metal layer, except for the part embedded in the wiring groove, are removed by chemical mechanical polishing (CMP), so that the metal is embedded only in the wiring groove, thereby forming a metal wiring.

This involves contact with the air once after CMP, resulting in the formation of an oxide on the metal wiring.

### <Second Step>

The second step is a step of preparing, as an etching solution, a solution in which a β-diketone containing a trifluoromethyl group and a carbonyl group bonded together is dissolved in an organic solvent.

### <Third Step>

The third step is a step of bringing an oxidant into contact with the surface of the semiconductor substrate to form a second metal oxide layer on a surface layer of at least the second metal layer. In the third step, a first metal oxide layer may be formed on a surface layer of the first metal layer.

As the semiconductor substrate has a structure in which the second metal layer is exposed on the surface, the oxide layer is formed on the front exposed surface. Further, the semiconductor substrate may have a structure in which the first metal layer is exposed. In the present disclosure, even with a structure in which the first metal layer is exposed on the semiconductor substrate, the second metal layer can be selectively etched because the etching rate of the second metal layer is higher than the etching rate of the first metal layer.

In the third step, any oxidant may be used that can form an oxide layer on a surface layer of the second metal layer and does not affect the semiconductor substrate due to corrosion, etc. For example, the oxidant may be oxygen, air, ozone, a peroxide, etc. Specific examples of the peroxide include hydrogen peroxide, peracetic acid, perbenzoic acid, sodium percarbonate, ammonium persulfate, sodium persulfate, potassium persulfate, and potassium peroxysulfate. These may be used alone or in admixtures of two or more.

When these oxidants are solid per se, it is convenient to dilute them with a solvent for use in solution form. Examples of solvents that may be used to dilute the above-mentioned peroxides include water, the later-described organic solvents, and mixtures thereof. Any conventionally known solvent capable of dissolving the peroxides can be used. Water is preferred as a main solvent for easily dissolving the peroxides. Here, the term “main solvent” means that it is present in an amount of at least 50 parts by mass based on 100 parts by mass of the diluent solvent(s).

Considering the contact time with these oxidants and the effect of improving the roughness of the metal-containing film after wet etching, the amount of oxidant in the solution prepared with a diluent solvent is preferably 0.01 to 50 parts by mass, more preferably 0.02 to 20 parts by mass, particularly preferably 0.05 to 10 parts by mass relative to 100 parts by mass of the solution.

Moreover, when the oxidant used is a gas such as oxygen, air, or ozone, a method is used in which the semiconductor substrate (workpiece) prepared in the first step is exposed to the gas or a gas mixture of the gas and an inert gas (e.g., nitrogen, argon, helium) in an etching device in which the workpiece is set. In one preferred embodiment, this method includes oxidizing the semiconductor substrate while rotating it horizontally as it can improve the contact efficiency between the second metal layer in the semiconductor substrate and the oxidant.

In the etching experimental examples described later, an oxide film is formed while rotating the semiconductor substrate. The rotational operation improves the contact efficiency between the oxidant and the surface of the metal layer. The higher the rotational speed, the more oxidized the surface layer of the second metal layer (cobalt or copper layer). Moreover, it can be found that the semiconductor substrate that was rotated at a higher speed and more oxidized has a higher etching rate of the second metal layer (cobalt or copper layer). This is believed to be because the β-diketone containing a trifluoromethyl group and a carbonyl group bonded together has a greater ability to complex with cobalt oxide or copper oxide than with the metal cobalt or copper per se. In contrast, it is believed that tungsten is not easily oxidized and its complexing ability changes little. Thus, in the third step, the second metal oxide layer is preferably formed while rotating the semiconductor substrate.

Moreover, in the method in which the workpiece is exposed to the gas (e.g., oxygen, air, ozone) or a gas mixture of the gas and an inert gas (e.g., nitrogen, argon, helium), the workpiece may be treated with a solution in which the gas or the gas mixture as an oxidant is dissolved.

When the etching solution of the present disclosure is used as this solution, and the etching solution in which the gas or the gas mixture is dissolved is brought into contact with the semiconductor substrate, an oxide layer can be formed on a surface layer of the second metal layer. Here, bringing the etching solution in which the gas or the gas mixture is dissolved into the contact with the semiconductor substrate is considered as one preferred embodiment of the present disclosure because it makes it possible to form an oxide layer on a surface layer of the second metal layer (third step) and simultaneously bring the etching solution into contact with the oxide layer (fourth step described later).

### <Fourth Step>

The fourth step is a step of bringing the etching solution into contact with the second metal oxide layer formed in the third step.

In the fourth step, the oxide layer formed on the surface layer of each metal layer may be reacted with the etching solution to form a metal complex, for example, by immersing in the etching solution the semiconductor substrate on which the metal layers are co-present, or placing the etching solution in an etching device in which the semiconductor substrate is set. The complex may be dissolved in the etching solution to remove the surface layer portion of the metal layer. Here, the oxide formed on the surface layer of the second metal layer may be removed with high selectivity with respect to the first metal layer due to the large difference in etching rate.

In the fourth step, the etching solution is preferably brought into contact with the second metal oxide layer while rotating the semiconductor substrate. The rotational operation improves the contact efficiency between the etching solution and the second metal oxide layer, which can increase the etching rate of the second metal layer. In particular, preferably, the second metal oxide layer is formed while rotating the semiconductor substrate in the third step, and the etching solution is brought into contact with the second metal oxide layer while rotating the semiconductor substrate in the fourth step.

In the fourth step, the temperature of the etching solution during etching is not limited as long as it is a temperature at which the etching solution is kept in the liquid form. The temperature can be appropriately selected within the range of about −10 to 100° C.

For example, hexafluoroacetylacetone and 1,1,1,3,5,5,5-heptafluoro-2,4-pentanedione have a boiling point of about 70° C., and trifluoroacetylacetone has a boiling point of about 105 to 107° C. Here, although the exactly measured melting points of hexafluoroacetylacetone and trifluoroacetylacetone are not known, since organic matter, when fluorinated, generally has lower melting and boiling points, and acetylacetone has a boiling point of 140° C. and a melting point of −23° C., the melting points of fluorinated hexafluoroacetylacetone and trifluoroacetylacetone are considered to be much lower.

Although the etching time is not limited, it is preferably within 60 minutes, considering the efficiency of the semiconductor device manufacturing process. Here, the etching time refers to the time during which the semiconductor substrate and the etching solution are in contact with each other. For example, it refers to the time during which the semiconductor substrate is immersed in the etching solution, or the time from when the etching solution is introduced inside a process chamber in which the substrate is set and etching is performed until the etching solution in the process chamber is then discharged to terminate the etching.

Moreover, in the fourth step, as some residual gas derived from the atmosphere or raw materials in the second step may be dissolved in the etching solution prepared in the second step, such residual gas may cause variations in etching rate. Thus, in order to adjust the etching rate reproducibly and precisely, the etching solution prepared in the second step is preferably degassed before contact with the second metal oxide layer.

Degassing may be performed by any method. Examples include a method in which an inert gas is used for bubbling to degas the residual gas from the etching solution (bubbling method); a method in which a container such as a pressure-resistant container is filled with the etching solution and then degassed using a vacuum pump (vacuum degassing method); a method in which the etching solution is heated for degassing (thermal degassing method); and a method in which the residual gas is degassed from the solution by gas permeation through a permeable membrane (membrane degassing method).

Among these, the method of using an inert gas for bubbling is a preferred degassing operation because the amount of residual gas in the etching solution can be reduced in a simple and low-cost manner. Examples of the inert gas include nitrogen, argon, and helium.

### <Washing Step>

The fourth step is preferably followed by washing with an organic solvent and further by drying.

The organic solvent during washing mentioned here may be one used in the etching solution or a conventionally known organic solvent. It should be noted that multiple types of water or organic solvents may be used in the washing.

It should be noted that the third step and the fourth step may not be continuous with each other. Since the oxidant used in the third step may affect the properties of the etching solution of the present disclosure, the wet etching method of the present disclosure may include a washing step between the third step and the fourth step.

The inclusion of such a washing step can reduce compositional changes of the active component for etching of the etching solution. Examples of the washing step include a method in which water, an organic solvent, or other solvent is brought into contact with the oxide layer to eliminate the oxidant from the surface layer of the second metal layer.

Any conventionally known organic solvent can be used in the washing step as long as it can dissolve the etching solution and/or the oxidant. For example, those mentioned earlier as examples for the organic solvent used in the etching solution may be used.

Here, alcohol and polyhydric alcohol derivatives are preferred in terms of solubility, with 2-propanol, propylene glycol monomethyl ether, and propylene glycol monomethyl ether acetate being particularly preferred. Moreover, multiple types of water or organic solvents may be used in the washing step.

### <Selectivity>

In the present disclosure, the phrase “selectively etching the second metal layer using the etching solution” means that the second metal layer can be selectively etched as the etching rate of the second metal layer is higher than the etching rate of the first metal layer and etching of the first metal layer is thus suppressed. For example, a significant etching effect with high selectivity of the second metal layer with respect to the first metal layer is observed when the ratio (B/A) of the etching rate (B) of the second metal layer to the etching rate (A) of the first metal layer is 3 or more, preferably 10 or more, more preferably 50 or more. The upper limit of the ratio (B/A) of the etching rate (B) of the second metal layer to the etching rate (A) of the first metal layer is not limited, but the ratio B/A may be 500 or less, for example.

Moreover, as an example of the determination of the etching effect with high selectivity with respect to metals, the method described in Patent Literature 2 discloses the etching rate measurement and etching selectivity using a substrate obtained by film formation by sputtering a titanium-based metal, a tungsten-based metal, etc. This method may also be applied to the etching solution of the present disclosure and the etching method using the etching solution; as shown in the etching experimental examples described later, a semiconductor substrate with a tungsten film formed thereon and a semiconductor substrate with a cobalt and/or copper film formed thereon may be prepared, and the oxide layer formation method and the etching method of the present disclosure may be applied to these semiconductor substrates to measure the etching rates of the tungsten, cobalt, and copper layers on the semiconductor substrates and to evaluate the etching selectivity.

### <Device>

A high performance device can be produced by employing the wet etching method of the present disclosure. The device according to the present disclosure can be produced at low cost with the use of a metal-containing film etched by the wet etching method according to the present disclosure. Examples of such devices include solar cells, hard disk drives, logic ICs, microprocessors, dynamic random access memory devices, phase change memory devices, ferroelectric memory devices, magnetoresistive memory devices, resistance change memory devices, and MEMS.

### EXAMPLES

Hereinafter, the present disclosure is described in detail with reference to examples, but the present disclosure is not limited to these examples.

### Evaluation Method

### <Measurement of Etching Amount>

The etching amount was determined by measuring the weight before and after the treatment using a precision balance and calculating the amount of change. Moreover, the etching rate is determined as: Etching amount [nm]/Contact time [min] with etching solution.

### <Measurement of Surface Roughness>

The surface of the metal layer before etching (initial state) and the surface of the metal layer after etching were measured by atomic force microscope AFM (SHIMADZU SPM-9700; scanning range: 1.00 μm; scanning speed: 1.0 Hz) to determine the centerline average roughness Ra (nm) and the difference in Ra (ΔRa) before and after etching. Here, the “Ra” is a three-dimensional extension of the centerline average roughness defined by JIS B 0601 applied to the measurement surface, and was calculated as “the average of the absolute values of deviation between the reference surface and the specified surface” using the following equation:

$$Ra = \frac{1}{{S}_{0}} {\int }_{{Y}_{T}}^{{Y}_{B}} {\int }_{{X}_{L}}^{{X}_{R}} \vert F ( X , Y ) - {Z}_{0} \vert dXdY \qquad [ Math . 1 ]$$

wherein X_{L} and X_{R} represent a measurement range of X-coordinates, and Y_{B} and Y_{T} represent a measurement range of Y-coordinates; S₀ represents the area of the measurement surface on the assumption that it is an ideally flat surface, and is the value of (X_{R}−X_{L})×(Y_{B}−Y_{T}); F(X,Y) represents the height at a measurement point (X,Y); and Z₀ represents the average height within the measurement surface.

### <Etching Experimental Example>

In the following etching experimental examples, with reference to the method of Patent Literature 2, cobalt, copper, and tungsten, and semiconductor substrates with films of these metals formed thereon were prepared and brought into contact with the etching solution of the present disclosure to compare the etching rates and determine the selectivity.

First, a 2 cm×2 cm silicon substrate having a 0.1 mm-thick metal film was used as a semiconductor substrate sample.

The metal film was formed by sputtering or chemical vapor deposition (CVD).

Next, an etching solution was prepared by mixing hexafluoroacetylacetone (HFAc) with propylene glycol-1-monomethyl ether-2-acetate (PGMEA) as a solvent to a HFAc concentration of 5 mass %. Subsequently, the following experiments were performed. It should be noted that the prepared etching solution had a moisture content of 70 ppm.

### Experimental Example 1

### Etching; Examples 1 to 3

A silicon wafer with a cobalt (Co) film formed thereon, a silicon wafer with a copper (Cu) film formed thereon, and a silicon wafer with a tungsten (W) film formed thereon as workpieces were set in a spin coater.

Next, dry air (3 L/min) as an oxidant was introduced into the spin coater. While the silicon wafer with a cobalt film formed thereon, the silicon wafer with a copper film formed thereon, and the silicon wafer with a tungsten film formed thereon were exposed to the oxidant, the wafers were rotated at 1000 rpm (Example 1), 2000 rpm (Example 2), or 4000 rpm (Example 3) for 60 seconds, whereby metal oxide films having different degrees of oxidation were formed.

Subsequently, 1 mL of the etching solution (5% HFAc/PGMEA) was added dropwise from above every 10 seconds. Here, the etching solution was added dropwise while rotating each wafer at the rotational speed indicated above.

After being treated for a certain period of time, the wafers were washed with isopropyl alcohol (IPA) and further dried with N₂.

As the results of the etching tests, Table 1 shows the etching rates of the Co wafer, Cu wafer, and W wafer with respect to the rotational speeds of the spin coater, the selectivity of Co with respect to W, and the selectivity of Cu with respect to W (Examples 1 to 3).

TABLE 1

| | Rotational | | Etching rate | | | | |
|---|---|---|---|---|---|---|---|
| | speed of spin | | nm/min | | | Selectivity | Selectivity |
| | coater (rpm) | Atmosphere | Co wafer | Cu wafer | W wafer | Co/W | Cu/W |
| Example 1 | 1000 | Air | 1.62 | 0.43 | 0.078 | 21 | 6 |
| Example 2 | 2000 | Air | 2.70 | 0.68 | 0.046 | 56 | 15 |
| Example 3 | 4000 | Air | 3.72 | 0.88 | 0.03 | 124 | 29 |

As shown in Examples 1 to 3, the etching rate of the Co wafer was enhanced as the rotational speed of the spin coater was increased. In Example 3 in which the wafers were treated at 4000 rpm, the etching rate of the Co wafer was further enhanced to 3.72 nm/min, while the etching rate of the W wafer was 0.03 nm/min, resulting in a Co/W selectivity of 124 as a very good result. Also, for the Cu wafer, in Example 3 in which the wafers were treated at 4000 rpm, the etching rate of the Cu wafer was 0.88 nm/min, resulting in a Cu/W selectivity of 29 as a good result.

This shows that Co and Cu are more easily complexed as they are more oxidized, while W is not easily oxidized and that the use of the metal oxide films enables selective etching with the wet etching solution of the present disclosure.

### Experimental Example 2

### Etching; Example 4, Example 5, and Comparative Examples 1 to 4

Cobalt and copper metal pieces (coupons) were etched under the same conditions as in Experimental Example 1 for any duration of time (until the etching was stopped, with a portion of the formed cobalt or copper film remaining on the surface without being etched) using an etching solution prepared under the same conditions as in Experimental Example 1, acetylacetone, and acidic aqueous solutions (phosphoric acid (H₃PO₄), acetic acid (AcOH)/ammonia water (AcOH/NH₄OH), and iron (III) chloride/copper (II) chloride) as etching solutions.

In Experimental Example 2, the change in roughness (difference in Ra; ΔRa) before and after etching was measured by AFM. A smaller such difference is considered as a better result. Table 2 shows the results (Example 4, Example 5, and Comparative Examples 1 to 4).

TABLE 2

| | | Etching solution | | Change in roughness (nm) | | | |
|---|---|---|---|---|---|---|---|
| | Atmosphere | Main component | Solvent | Cobalt | Copper | Tungsten | Evaluation |
| Example 4 | Air | HFAc | PGMEA | 0.0 | 0.2 | <0.05 | Good |
| Example 5 | Air | HFAc | IPA | 0.1 | 0.3 | <0.05 | Good |
| Comparative Example 1 | Air | acetylacetone | IPA | 2.0 | 1.9 | <0.05 | Poor |
| Comparative Example 2 | Air | H₃PO₄ | Water | 4.8 | 3.6 | 1.6 | Poor |
| Comparative Example 3 | Air | AcOH/NH₄OH | Water | 0.5 | 0.6 | 1.4 | Poor |
| Comparative Example 4 | Air | FeCl₃/CuCl₂ | Water | 7.0 | 3.9 | 1.7 | Poor |

*In the table, IPA represents isopropyl alcohol, and Ac represents an acetyl group.

The results show that in Examples 4 and 5 with conditions in which HFAc is used as the etching solution in an air atmosphere, etching of Co or Cu can be performed without increasing the change in roughness. It is also shown that there is no impact on the change in roughness of W.

In contrast, the results show that in Comparative Examples 1 to 4 with conditions in which acetylacetone or any of the acidic aqueous solutions is used as the etching solution, the change in roughness of Co or Cu is large, or the change in roughness of W is large.

The wet etching solution and the wet etching method of the present disclosure are not limited to the embodiments described above. Various modifications and alterations can be made to the components and production method of the wet etching solution as well as the steps of the wet etching method, etc. without departing from the scope of the present disclosure.

The present application claims priority under the Paris Convention and the law of the designated state to Japanese Patent Application No. 2021-001370 filed on Jan. 7, 2021. The entire contents of the latter application are hereby incorporated by reference.

1. A wet etching solution for selectively removing a second metal layer made of at least one of a cobalt-based material or a copper-based material from a semiconductor substrate while suppressing etching of a first metal layer made of a tungsten-based material,
the first metal layer and the second metal layer being co-present on the semiconductor substrate,
an oxide layer being formed on a surface layer of at least the at least one of a cobalt-based material or a copper-based material,
the etching solution comprising a solution in which a β-diketone containing a trifluoromethyl group and a carbonyl group bonded together is dissolved in an organic solvent.

2. The wet etching solution according to claim 1,
wherein a material of the semiconductor substrate is a silicon-based material or a silicate glass material.

3. The wet etching solution according to claim 1, wherein the β-diketone is present at a concentration of 1 to 80 mass %.

4. The wet etching solution according to claim 1, wherein the etching solution has a moisture content of 1 mass % or less.

5. A wet etching method of selectively removing a second metal layer made of at least one of a cobalt-based material or a copper-based material with respect to a first metal layer made of a tungsten-based material, the method comprising:
a third step of bringing an oxidant into contact with a semiconductor substrate on which the first metal layer and the second metal layer are co-present, to form a second metal oxide layer on a surface layer of at least the second metal layer; and
a fourth step of bringing the second metal oxide layer into contact with an etching solution which comprises a solution in which a β-diketone containing a trifluoromethyl group and a carbonyl group bonded together is dissolved in an organic solvent.

6. The wet etching method according to claim 5, wherein in the third step, the oxidant is oxygen, air, ozone, or a peroxide.

7. The wet etching method according to claim 5,
wherein the fourth step comprises bringing the etching solution into contact with the second metal oxide layer after degassing the etching solution.

8. The wet etching method according to claim 5,
wherein the third step and the fourth step are simultaneously performed using a solution in which at least one gas selected from oxygen, air, and ozone as the oxidant is dissolved in the etching solution.

9. The wet etching solution according to claim 1,
wherein at least one gas selected from oxygen, air, and ozone as an oxidant is dissolved in the etching solution.

10. The wet etching solution according to claim 1,
wherein the etching solution further comprises an acid.

11. The wet etching solution according to claim 10,
wherein the acid is at least one selected from the group consisting of citric acid, formic acid, acetic acid, and trifluoroacetic acid.

12. The wet etching method according to claim 5,
wherein a material of the semiconductor substrate is a silicon-based material or a silicate glass material.

13. The wet etching method according to claim 5,
wherein the β-diketone is present in the etching solution at a concentration of 1 to 80 mass %.

14. The wet etching method according to claim 5,
wherein the etching solution has a moisture content of 1 mass % or less.

15. The wet etching method according to claim 5,
wherein the etching solution further comprises an acid.

16. The wet etching method according to claim 15,
wherein the acid is at least one selected from the group consisting of citric acid, formic acid, acetic acid, and trifluoroacetic acid.

17. The wet etching method according to claim 5,
wherein, in the third step, the oxidant used is at least one gas selected from the group consisting of oxygen, air, and ozone, and the semiconductor substrate is oxidized by exposing the semiconductor substrate to the gas while rotating it horizontally.

18. The wet etching method according to claim 17,
wherein the semiconductor substrate is rotated at 1000 rpm or more.

19. The wet etching method according to claim 5,
wherein, in the fourth step, the second metal oxide layer is brought into contact with the etching solution while rotating the semiconductor substrate.

20. The wet etching method according to claim 19,
wherein the semiconductor substrate is rotated at 1000 rpm or more.
